(19) United States
(12) Patent Application Publication
(10) Pub. No.: US 2026/0139369 A1
(43) Pub. Date: May 21, 2026

(54) REDUCING PARTICLE BUILDUP IN PROCESSING CHAMBERS

(71) Applicant: Lam Research Corporation, Fremont, CA (US)

(72) Inventors: Chad Adrien BEAUDETTE, Wilsonville, OR (US); Yanhui HUANG, Sherwood, OR (US); Brandt HENRI, Beaverton, OR (US); Xing Yi HU, Xiang Yang (CN)

(21) Appl. No.: 19/119,736

(22) PCT Filed: Oct. 9, 2023
(86) PCT No.: PCT/US2023/076389

§ 371 Date: Apr. 9, 2025

Related U.S. Application Data
(60) Provisional application No. 63/381,843, filed on Nov. 1, 2022.

(51) Int. Cl. C23C 16/44; C23C 16/455; C23C 16/505; C23C 16/52

(52) U.S. Cl. CPC C23C 16/4404; C23C 16/4405; C23C 16/4408; C23C 16/45565; C23C 16/505; C23C 16/52

(57) ABSTRACT

Systems and methods for operating a deposition tool are provided. In one aspect, the method includes processing a substrate in a processing chamber including a ceramic showerhead and a coating. The coating includes material deposited in the processing chamber. The ceramic showerhead is heated to a processing temperature during the processing of the substrate. The method further includes performing a cleaning process to remove the coating by introducing a reactive cleaning species into the processing chamber while flowing a purge gas through the ceramic showerhead and by heating the ceramic showerhead to a bake-out temperature above the processing temperature to remove at least some aluminum fluoride particles generated during the cleaning process. The method further includes applying a new coating to the processing chamber.

### BACKGROUND

Electronic device fabrication processes may involve many steps of material deposition, patterning, and removal to form integrated circuits on substrates. For example, chemical vapor deposition (CVD) can be used to deposit a film on a substrate by exposing the substrate to a flow of one or more gas-phase film precursors. The film precursors react to form the film on the substrate. Plasma-enhanced CVD (PECVD) utilizes a plasma to form reactive species from the film precursors to facilitate deposition.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed related to reducing particle buildup in processing chambers from cleaning processes. One example provides a method for operating a deposition tool. The method comprises processing a substrate in a processing chamber. The processing chamber comprises a ceramic showerhead and a coating. The ceramic showerhead is heated to a processing temperature during the processing of the substrate. The method further comprises performing a cleaning process to remove the coating. The cleaning process is performed by introducing a reactive cleaning species into the processing chamber while flowing a purge gas through the ceramic showerhead. The method further comprises heating the showerhead to a bake-out temperature after the cleaning process. The bake-out temperature is above the processing temperature. The heating process is performed to remove at least some particles generated during the cleaning process. The method further comprises applying a new coating the processing chamber.

In some such examples, applying the new coating additionally or alternatively comprises applying one or more of a silicon oxide or a silicon nitride coating to surfaces within the processing chamber.

In some such examples, the method additionally or alternatively comprises cooling the ceramic showerhead to the processing temperature before applying the new coating.

In some such examples, the heating process additionally or alternatively comprises heating the showerhead to a bake-out temperature of at least 520 degrees Celsius.

In some such examples, performing a cleaning process additionally or alternatively comprises flowing the purge gas through the ceramic showerhead at a flow rate of at least 7,500 standard cubic centimeters per minute.

In some such examples, performing a cleaning process additionally or alternatively comprises flowing the purge gas through the ceramic showerhead at a flow rate of at least 10,000 standard cubic centimeters per minute.

In some such examples, the ceramic showerhead additionally or alternatively comprises aluminum nitride and the particles comprise aluminum fluoride.

In some such examples, the processing chamber additionally or alternatively comprises an insert disposed within an outlet of the ceramic showerhead, and heating the ceramic showerhead to the bake-out temperature additionally or alternatively comprises dislodging at least some particles from between a wall of the outlet and a side of the insert.

Another example provides a deposition tool. The deposition tool comprises a processing chamber. The deposition tool further comprises a showerhead for introducing processing gases into the processing chamber. The showerhead comprises a heater. The deposition tool further comprises a plasma generator in fluid communication with the processing chamber. The deposition tool further comprises a controller. The controller comprises executable instructions to control the deposition tool. The executable instructions are configured to control the deposition tool to apply a first coating to the processing chamber. The executable instructions are further configured to control the deposition tool to heat the showerhead to a processing temperature. The executable instructions are further configured to control the deposition tool to process a substrate in the processing chamber. The executable instructions are further configured to control the deposition tool to flow a purge gas through the showerhead. The executable instructions are further configured to control the deposition tool to generate a reactive cleaning species using the plasma generator to remove the first coating. The executable instructions are further configured to control the deposition tool to heat the showerhead to a bake-out temperature. The bake-out temperature is above the processing temperature. The showerhead is heated using the heater to remove at least some aluminum fluoride particles generated during the removal of the first coating. The executable instructions are further configured to control the deposition tool to apply a second coating to the processing chamber.

In some such examples, applying the second coating additionally or alternatively comprises applying one or more of a silicon oxide or a silicon nitride layer to surfaces within the processing chamber.

In some such examples, the controller additionally or alternatively comprises instructions executable to cool the showerhead to the processing temperature before applying the second coating.

In some such examples, the instructions executable to heat the showerhead to the bake-out temperature are additionally or alternatively executable to heat the showerhead to a temperature of at least 520 degrees Celsius.

In some such examples, the instructions executable to flow the purge gas through the showerhead are additionally or alternatively executable to flow the purge gas at a flow rate of at least 7,500 standard cubic centimeters per minute.

In some such examples, the instructions executable to flow the purge gas through the showerhead are additionally or alternatively executable to flow the purge gas at a flow rate of at least 10,000 standard cubic centimeters per minute.

In some such examples, the showerhead additionally or alternatively comprises aluminum nitride.

In some such examples, the reactive cleaning species additionally or alternatively comprise fluorine radicals.

Another example provides a method for operating a deposition tool. The method comprises performing a first plurality of substrate batch processing cycles in a processing chamber. The processing chamber comprises a ceramic showerhead. Each substrate batch processing cycle comprises applying a coating to the processing chamber. Each substrate batch processing cycle further comprises processing a batch of substrates. Each substrate batch processing cycle further comprises performing a cleaning process to remove the coating from the processing chamber. The method further comprises performing an in situ crystal removal process to etch crystals extending from the showerhead. The in situ crystal removal process is performed after performing the first plurality of substrate batch processing cycles.

In some such examples, performing the in situ crystal removal process additionally or alternatively comprises introducing a reactive cleaning species into the processing chamber while flowing a purge gas through the ceramic showerhead, wherein the purge gas is introduced through the ceramic showerhead at a flow rate of equal to or less than 3,000 standard cubic centimeters per minute.

In some such examples, performing the in situ crystal removal process additionally or alternatively comprises performing a plurality of crystal etch process cycles, wherein each crystal etch process cycle comprises introducing a reactive cleaning species into the processing chamber while flowing a purge gas through the ceramic showerhead.

In some such examples, the plurality of substrates is processed at a processing temperature, and the method additionally or alternatively further comprises heating the ceramic showerhead to a bake-out temperature above the processing temperature to remove at least some aluminum fluoride particles generated during the cleaning process.

### BRIEF DESCRIPTION OF THE DRAWINGS

FIG. 1 shows an example PECVD tool for backside substrate deposition.

FIG. 2 shows an example PECVD tool for frontside substrate deposition.

FIG. 3A shows a perspective view of an example showerhead.

FIG. 3B shows a bottom view of the showerhead of FIG. 3A.

FIG. 4A shows a perspective view of an example insert.

FIG. 4B shows a top view of the insert of FIG. 4A.

FIG. 4C shows a bottom view of the insert of FIG. 4A.

FIG. 5 shows a schematic side view of an example insert disposed within a showerhead.

FIG. 6 schematically shows example locations at which particles can form on a showerhead-insert structure during a cleaning process.

FIG. 7 shows a flow diagram of an example method for mitigating particle generation in a cleaning process.

FIG. 8 shows a flow diagram of an example method for etching crystal deposits from a showerhead outlet.

FIG. 9 schematically shows an example embodiment of a computing system.

### DETAILED DESCRIPTION

The term “atomic layer deposition” (ALD) may generally represent a process in which a film is formed on a substrate in one or more individual layers by sequentially adsorbing a precursor conformally to the substrate and reacting the adsorbed precursor to form a film layer. Examples of ALD processes comprise plasma-enhanced ALD (PEALD), remote plasma-enhanced ALD (RPEALD) and thermal ALD (TALD).

The term “bake-out” may generally represent a process in which a showerhead is heated to cause thermal expansion of the showerhead. The thermal expansion dislodges particles from surfaces of the showerhead. The term “bake-out temperature” may generally represent a temperature to which a showerhead is heated to cause thermal expansion-driven dislodging of particles.

The term “cleaning process” may generally represent a process in which a coating in a deposition chamber is removed by reactive cleaning species formed in a plasma.

The term “chemical vapor deposition” (CVD) may generally represent a process in which a solid phase film is formed on a substrate by directing a flow of one or more precursor gases over the substrate surface under conditions configured to cause the chemical conversion of the precursor gases to the solid phase film. The term “plasma-enhanced chemical-vapor deposition” (PECVD) may generally represent a CVD process in which a plasma is used to facilitate the chemical conversion of one or more precursor gases to a solid phase film on a substrate. The terms “growth”, “deposition”, and variants thereof, also may be used to refer to film formation.

The term “coating” may generally represent one or more material layers deposited on interior surfaces of a processing chamber prior to performing a deposition process on a substrate in the processing chamber. Example coatings may comprise one or more of silicon oxide or silicon nitride. A coating may comprise sublayers. Example sublayers include a precoat and an undercoat. The term “undercoat” may generally refer to a coating sublayer formed directly on interior surfaces of a processing chamber. The term “precoat” may generally refer to a coating that is formed over an undercoat.

The term “crystal” may generally represent a crystalline deposit that forms at an outlet of a showerhead over time. A crystal may extend away from a showerhead toward a pedestal.

The term “deposition tool” may generally represent a processing tool configured to form films on substrates. Example deposition tools include ALD tools and CVD tools.

The term “fluid communication” may generally represent a capability of a fluid to flow from one location to another location.

The term “heater” may generally represent a heater configured to heat a component within a processing chamber. In some examples, a heater may be incorporated into a showerhead.

The term “inlet” may generally represent an opening through which a processing gas may enter a structure. The term “outlet” may generally represent an opening through which a processing gas may exit a structure. For example, a showerhead comprises an inlet through which a processing gas enters the showerhead and an outlet through which the processing gas flows into a processing chamber. As another example, a processing chamber comprises through which gases flow to a chamber evacuation system.

The term “insert” may generally represent a component that fits within an outlet of a showerhead. An insert comprises one or more processing gas openings that are smaller than the outlet of the showerhead. An insert may be formed from a different material than a showerhead.

The term “pedestal” may generally represent a structure configured to support a substrate within a processing chamber.

The term “plasma” may generally represent a gas comprising cations and free electrons. The term “in-situ plasma” may generally represent a plasma formed in a space between a pedestal and a showerhead in a processing chamber. The term “remote plasma” may generally represent a plasma generated at a location remote from a processing station of a processing tool.

The term “plasma generator” may generally represent a collection of components that can be used to form a plasma. The term “in situ plasma generator” may generally represent a combination of components that can be used to form a plasma between a pedestal and a showerhead in a processing chamber. The term “remote plasma generator” may generally represent a combination of components that can be used to form a plasma at a location remote from a processing chamber

The term “processing chamber” may generally represent an enclosure in which chemical and/or physical processes are performed on substrates. Example chemical and/or physical processes include CVD and ALD processes.

The term “processing gas” may generally represent a gas-phase chemical used during a process performed in a processing chamber. Example processes include a cleaning process and a deposition process. Example processing gases include a precursor gas for a deposition process, a cleaning species precursor gas, and a purge gas.

The term “processing temperature” may generally represent a temperature at which a showerhead in a processing chamber is maintained during a deposition process.

The term “purge gas” may generally represent a gas used to remove at least a portion of processing gases from a processing chamber. Example purge gases include nitrogen (N₂), argon (Ar), neon (Ne), and helium (He).

The term “radical” may generally represent a chemical species that includes an unpaired electron.

The term “radiofrequency (RF) power source” may generally represent an apparatus that outputs RF power to electrodes to generate a plasma.

The term “reactive cleaning species” may generally represent one or more of an ion or a radical generated by the introduction of a cleaning species precursor to a plasma. An example cleaning species precursor is nitrogen trifluoride (NF₃). An example reactive cleaning species is a fluorine radical.

The term “remote plasma chamber” may generally represent an enclosure in which a plasma is generated at a location remote from a processing station of a processing chamber. A remote plasma chamber is configured to generate reactive species, such as reactive cleaning species, for introduction into a processing chamber after generation.

The term “showerhead” may generally represent a processing gas outlet comprising a plurality of holes distributed across an area.

The term “showerhead pedestal” may generally represent a pedestal comprising one or more processing gas outlets configured to expose a substrate surface facing the pedestal to a processing gas. A showerhead pedestal may be used to perform a CVD process on a substrate backside. The term “substrate backside” may generally represent a side of a substrate opposite a side on which devices are fabricated.

The term “substrate” may generally represent any object on which a film can be deposited.

The term “substrate batch processing cycle” may generally represent a cycle comprising coating a deposition chamber, processing a batch of substrates, and performing a cleaning process to remove the coating.

As mentioned above, processes such as CVD and ALD may be used to deposit films on substrates. In some deposition processes, a coating is applied to processing chamber interior surfaces prior to film deposition. The coating may help to prevent outgassing from chamber walls and/or stabilize on-substrate performance across the batch of substrates. After a batch of substrates have been processed, the coating is cleaned from the chamber in a cleaning process prior to performing another coating process. The term “batch of substrates” as used herein may generally represent any number of substrates that are processed after a coating process is performed and before a cleaning process is performed.

A cleaning process may utilize reactive cleaning species generated in a plasma to clean a coating from chamber surfaces. For example, a remote plasma generator may be used to generate the reactive cleaning species. The reactive cleaning species react with materials on processing chamber surfaces to form volatile products. The volatile products are then evacuated from the processing chamber. As a more specific example, reactive cleaning species comprising fluorine radicals and fluorine-containing radicals (for example, the nitrogen difluoride (NF₂) radical) can be generated in a plasma from a fluorine-containing molecule such as nitrogen trifluoride. The term “fluorine radicals” is used to represent generally any radical species formed from a fluorine-containing molecule in a plasma. Fluorine radicals can be used to clean a silicon nitride and/or silicon oxide coating from a chamber by forming volatile compounds such as silicon tetrafluoride (SiF₄). In some examples, an in-situ plasma generator may be used alternatively or additionally to a remote plasma generator to generate reactive cleaning species.

However, fluorine radicals also can react with aluminum-containing ceramic components to form aluminum fluoride particles. As an example, aluminum fluoride (AlF₃) particles may form on surfaces of an aluminum nitride showerhead. Example surfaces include surfaces within a showerhead plenum, surfaces between a showerhead outlet wall and an insert positioned in the outlet, and surfaces on a showerhead face. The particles may dislodge from the aluminum-containing components during a later deposition process. The particles can contaminate a substrate and cause defects. One method of removing such particles is performing a wet clean of the affected components. However, performing a wet clean can be time-consuming. The wet clean process includes waiting for processing chamber components to cool, purging the processing chamber to remove any residual processing gases, opening the processing chamber, and then cleaning surfaces inside the processing chamber. The overall process can take several hours. The resulting system downtime can reduce system yield.

Thus, examples are disclosed that relate to mitigating risks arising from particles generated during a deposition chamber cleaning process. As one example, particle formation within a showerhead plenum can be mitigated by flowing a purge gas through the showerhead plenum at a flow rate sufficient to reduce reactive cleaning species backflow into the showerhead plenum during the cleaning process. Particles generated between walls of showerhead openings and inserts can be at least partially removed by heating the showerhead to a temperature above a substrate processing temperature. The heating may dislodge aluminum fluoride particles by thermal expansion of the showerhead and/or the insert. This heating also may be referred to as a bake-out process. Particles on a face of a showerhead also can be at least partially removed by the bake-out process. The dislodged particles then can be removed by a chamber evacuation system. These examples and others are described in more detail below.

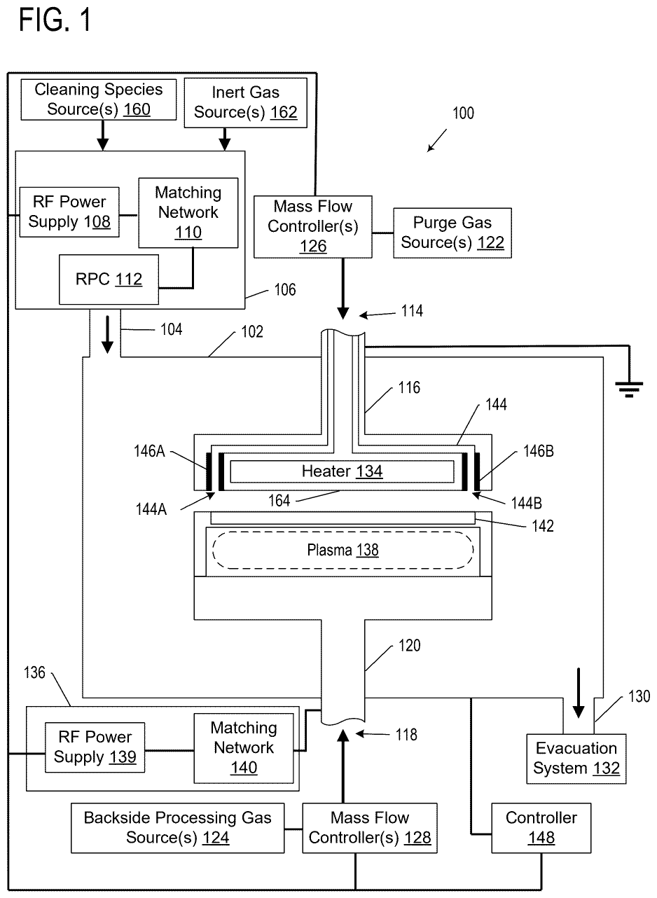

FIG. 1 shows an example deposition tool 100 configured for backside deposition. The deposition tool 100 includes a processing chamber 102. The processing chamber 102 includes a remote plasma inlet 104 for introducing reactive cleaning species from a remote plasma generator 106 for a cleaning process. The remote plasma generator 106 comprises a radiofrequency (RF) power supply 108, an impedance matching network 110, and a remote plasma chamber (RPC) 112. The remote plasma chamber 112 comprises components configured to form an inductively coupled plasma or a capacitively coupled plasma. In other examples, the remote plasma generator 106 may be configured to form a microwave plasma.

The processing chamber 102 further comprises a purge gas inlet 114 for introducing a purge gas into a showerhead 116. The processing chamber 102 further comprises a backside processing chemical inlet 118 for introducing a gas-phase processing chemical to a showerhead pedestal 120 to perform a backside CVD process. The purge gas inlet 114 is in fluid communication with one or more purge gas source(s) 122. The backside processing gas inlet 118 is in fluid communication with one or more backside processing gas source(s) 124. The purge gas inlet 114 is further in fluid communication with one or more mass flow controller(s) 126. The backside processing gas inlet 118 is further in fluid communication with one or more mass flow controller(s) 128. The mass flow controllers 126, 128 respectively can be used to control the flow rates of one or more purge gases and one or more backside processing gases into the processing chamber 102. The processing chamber 102 further includes an outlet 130 for evacuating waste, by-products, contaminants, and other gases and particles from the processing chamber 102 via a chamber evacuation system 132.

The processing chamber 102 can include various heaters. For example, showerhead 116 includes a heater 134. In some implementations, the pedestal showerhead 120 also includes a heater.

In some examples, processing chamber 102 may comprise an in-situ plasma generator 136 to generate a plasma 138 for performing a backside PECVD process. The in-situ plasma generator comprises a radiofrequency (RF) power supply 139 and an impedance matching network 140.

During processing, a substrate 142 is placed on the showerhead pedestal 120. A backside deposition processing gas is introduced into the backside processing gas inlet 118. The in-situ plasma generator 136 is used to generate the plasma 138. Further, a flow of purge gas is directed toward the front side of the substrate 142. The purge gas comprises one or more inert gases. Example inert gases include nitrogen, argon, neon, helium, krypton, and xenon. The purge gas helps to prevent deposition of material on the frontside of the substrate 142.

The showerhead 116 includes a plurality of purge gas outlets in fluid communication with purge gas inlet 114 via a showerhead plenum 144. Two purge gas outlets 144A, 144B are shown in FIG. 1 for simplicity, but the showerhead may have other purge gas outlets.

The showerhead 116 further includes a plurality of inserts, including inserts 146A, 146B. The inserts 146A, 146B are respectively disposed within the purge gas outlets 144A, 144B of the showerhead 116. Each insert 146A, 146B includes one or more purge gas openings. Two inserts 146A, 146B are shown in FIG. 1 for respective purge gas outlets 144A, 144B. However, the showerhead may have other inserts for other purge gas outlets. Example inserts are described in more detail below

The showerhead 116 can be made at least partially of a ceramic material. An example ceramic material is aluminum nitride. The inserts 146A, 146B can be made at least partially from a different ceramic material. An example includes aluminum oxide.

As mentioned above, precursor gases for a backside deposition process can be introduced through the showerhead pedestal 120. Application of RF power from the RF power supply 139 to the showerhead pedestal 120 excites the precursor gases into a plasma 138. Examples of films that can be deposited by backside deposition include silicon dioxide, silicon nitride, silicon oxynitride, silicon carbide, and amorphous silicon.

The deposition tool 100 can be configured to perform a coating process before processing of the substrate 142 to form a coating on surfaces within the processing chamber 102. Precursors for a coating process may be applied by introducing coating precursors through backside processing gas inlet 118 in the absence of a substrate. In some examples, a coating may comprise two or more layers. Examples include an undercoat layer, and a precoat layer over the undercoat. The undercoat and precoat can be formed of a similar material or materials as a material to be deposited on a substrate backside.

After processing a batch of substrates, a cleaning process can be performed to remove the coating and deposition residues from surfaces within the processing chamber 102. The cleaning process comprises introducing a reactive cleaning species into the processing chamber 102. The reactive cleaning species are formed by introducing one or more cleaning species precursors from one or more cleaning species precursor sources 160 into remote plasma chamber 112. An example cleaning species precursor for generating reactive cleaning species is nitrogen trifluoride. One or more inert gases also may be introduced into the remote plasma chamber 112 from one or more inert gas sources 162. Example inert gases include those listed above. The reactive cleaning species are introduced via the remote plasma cleaning inlet 104. The reactive cleaning species reacts with deposited materials on surfaces within the processing chamber 102 to form volatile products. The volatile products are exhausted from the processing chamber 102 through the outlet 130.

As mentioned above, the use of fluorine radicals as a reactive cleaning species can cause aluminum fluoride particles to form on surfaces of components made from aluminum nitride. Aluminum fluoride particles can form on surfaces within the showerhead plenum 144. Aluminum fluoride particles also can form within spaces between inserts 146A, 146B and walls of the respective purge gas outlets 140A, 140B. Aluminum fluoride particles also can form on a face 164 of the showerhead 116.

Aluminum fluoride particles can be removed using a wet clean process. However, as mentioned above, performing a wet clean process after preforming a chamber cleaning can be time consuming. As such, various processes can be performed to prevent aluminum fluoride formation on some surfaces and to remove aluminum fluoride particles from other surfaces after a cleaning process.

As one example, a bake-out process can be performed to remove aluminum fluoride particles from some surfaces. The bake-out process can be performed after a cleaning process. The bake-out process can include heating the showerhead 116 to a bake-out temperature. The heating process can be achieved using the heater 134. The bake-out temperature is higher than the processing temperature used for deposition processes in the processing chamber 102. In some implementations, the processing temperature for the showerhead is in the range of 200 degrees Celsius to 500 degrees Celsius. In such implementations, the bake-out temperature for the showerhead is at least 500 degrees Celsius. In some such examples, the bake-out temperature is at least 520 degrees Celsius. In further implementations, the bake-out temperature is at least 550 degrees Celsius.

During the bake-out process, the showerhead 116 and the inserts 146A, 146B undergo thermal expansion. The thermal expansion dislodges at least some particles from surfaces of the showerhead 116. Examples surfaces include surfaces between purge gas outlets 144A, 144B and inserts 146A, 146B, and on the face 164 of the showerhead 116. The dislodged particles can be removed from the processing chamber 102 through the outlet 130 during the bakeout process. In some examples, the bake-out temperature is maintained for a period of time, and then the showerhead is cooled. In other examples, cooling begins as soon as the bakeout temperature is reached. After cooling, a coating process is performed to apply a new coating to surfaces within the processing chamber. The new coating can comprise an undercoat and a precoat in some examples. Processing of a new batch of substrates can then be performed.

Alternatively or additionally to removing formed particles using a bake-out process, a purge gas may be flowed through the showerhead plenum 144 at a sufficient flow rate at a high flow rate during the cleaning process to avoid particle formation in the showerhead plenum 144. At lower purge gas flow rates, fluorine radicals can diffuse though inserts 146A, 146B into the showerhead plenum 144. This diffusion also can be referred to as backflow. The fluorine radicals then can react with aluminum nitride of the showerhead 116 to form aluminum fluoride particles. Thus, the use of a sufficiently high flow rate of purge gas within showerhead plenum 144 during a cleaning process may help to prevent backflow of fluorine radicals. This may help to reduce particle formation in the showerhead plenum 144. In some implementations, purge gas is flowed through the showerhead 116 at a flow rate of at least 7,500 standard cubic centimeters per minute (sccm) during the cleaning process. In further implementations, purge gas is flowed through the showerhead 116 at a flow rate of at least 10,000 sccm during the cleaning process. Such flow rates help to reduce or prevent backflow of the cleaning gas into showerhead plenum 144.

The deposition tool 100 of FIG. 1 further includes a controller 148. The controller 148 can be in communication with various components. Examples include the remote plasma RF power supply 108, the in-situ plasma RF power supply 139, the heater 134, mass flow controllers 126, 128, and other components within the deposition tool 100. The controller 148 can include executable instructions to control the deposition tool 100 to perform various processes. Examples include deposition processes, cleaning processes, bake-out processes, and crystal etching processes, as described in more detail below.

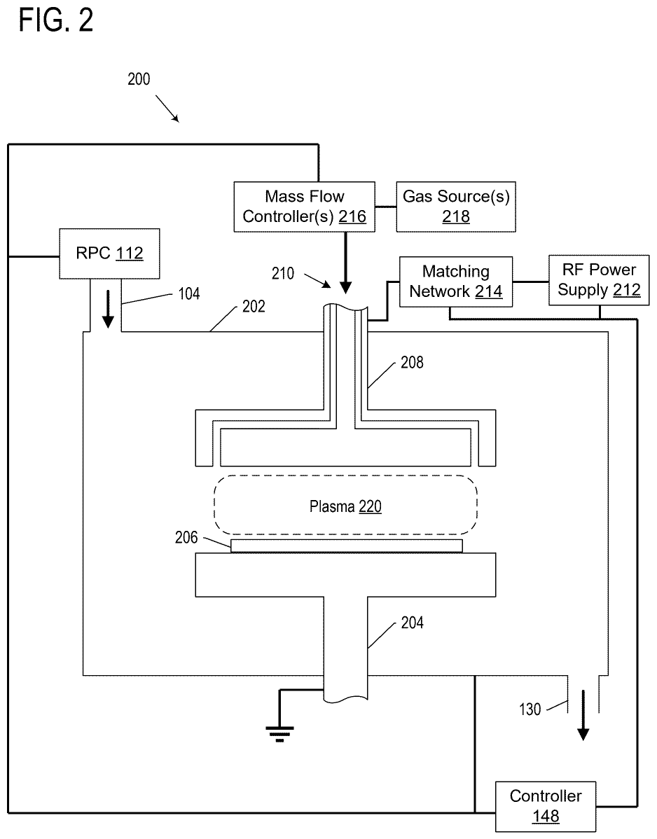

FIG. 2 shows another example deposition tool 200. The deposition tool 200 is configured for frontside PECVD processing. The deposition tool 200 includes a processing chamber 202. The processing chamber 202 includes a pedestal 204 for supporting a substrate 206 during processing. The processing chamber 202 further includes a showerhead 208 for introducing precursor gases via inlet 210. The showerhead 208 and pedestal 204 function as electrodes. The pedestal 204 is electrically grounded. The showerhead 208 is in communication with an RF power supply 212 and an RF matching network 214 for impedance matching. In other examples, the showerhead may be grounded, and RF power may be applied to the pedestal. During processing of the substrate 206, precursor gases are introduced via the showerhead 208. One or more mass flow controller(s) 216 control the flow of gases from one or more gas source(s) 218 through inlet 210. RF power applied to the showerhead 208 forms a plasma 220. The plasma 220 generates reactive species that react to form a film on the substate 206.

The showerhead 208 can be made at least partially of an aluminum-containing ceramic material, such as aluminum nitride. The showerhead 208 can react with fluorine radicals in a cleaning process to form aluminum fluoride particles. As such, the disclosed examples can be used to mitigate aluminum fluoride particle formation in the processing chamber 202. The disclosed examples also may be used with other processing tools that comprise ceramic showerheads. Examples include atomic layer deposition (ALD) tools.

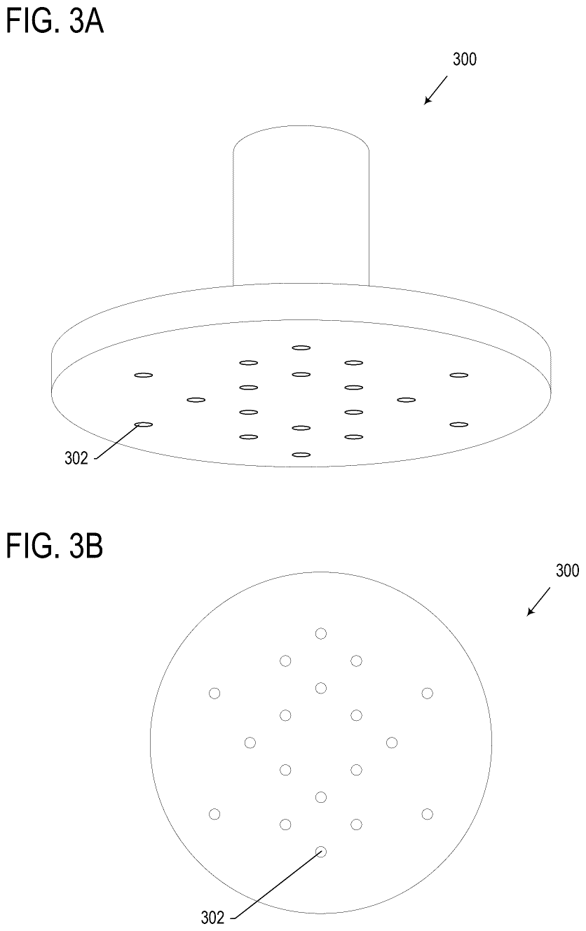

As described above, particle formation and buildup arising from a cleaning process can occur on various surfaces. FIG. 3A shows a perspective view of an example showerhead 300. FIG. 3B shows a bottom view of the showerhead 300. Showerhead 116 of FIG. 1 and showerhead 208 of FIG. 2 are examples of showerhead 300. Showerhead 300 includes a plurality of outlets 302 to disperse processing gases across a substrate surface. In this example, the showerhead 300 comprises twenty outlets 302. In other examples, a showerhead may have either a greater or lesser number of outlets 302. The plurality of outlets 302 can be configured with different patterns and offsets.

Each outlet 302 is in fluid communication with a plenum (not shown in FIG. 3) that is integrated within the showerhead 300. The plenum can be in fluid communication with a source of a processing gas. The specific type of processing gases in fluid communication with the plenum depends on the specific application of the showerhead 300. For example, where showerhead 300 represents an example of showerhead 116, the plenum may be in communication with a source of purge gas for use during processing of substrates and cleaning processes. Where showerhead 300 represents an example of showerhead 208, the channels can be in fluid communication with a source of precursor gas(es) for film deposition.

In some examples, a showerhead may include relatively larger diameter openings 302 each configured to hold an insert. The insert can include openings that are smaller than outlets of the showerhead. The use of such inserts may facilitate manufacturing of the showerhead compared to forming smaller openings directly in the showerhead. In some examples, an insert may be made of aluminum oxide.

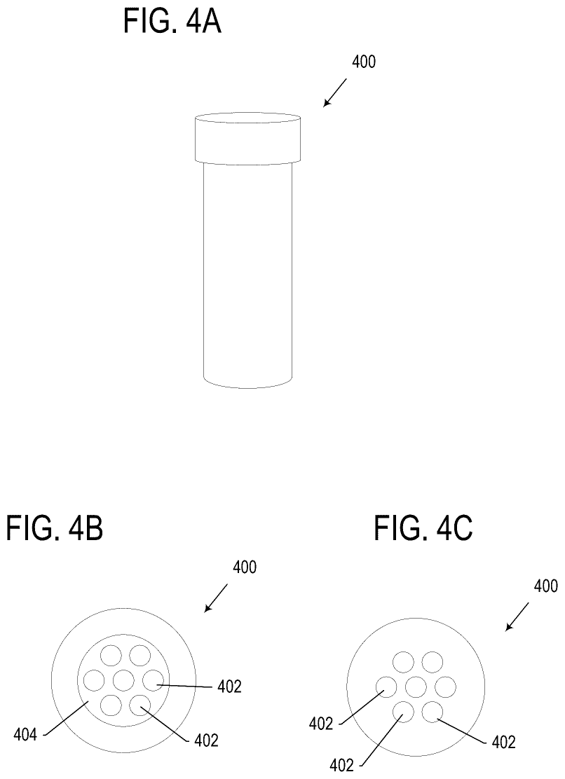

FIG. 4A shows a perspective view of an example insert 400. FIG. 4B shows a top view of the insert 400. FIG. 4C shows a bottom view of the insert 400. One end of the insert 400 includes a plurality of openings 402, each of which is smaller than an outlet of the showerhead. The plurality of openings 402 are in fluid communication with a single opening 404 at the other end of the insert 400. The insert 400 can be designed to fit within an outlet 302 of the showerhead 300.

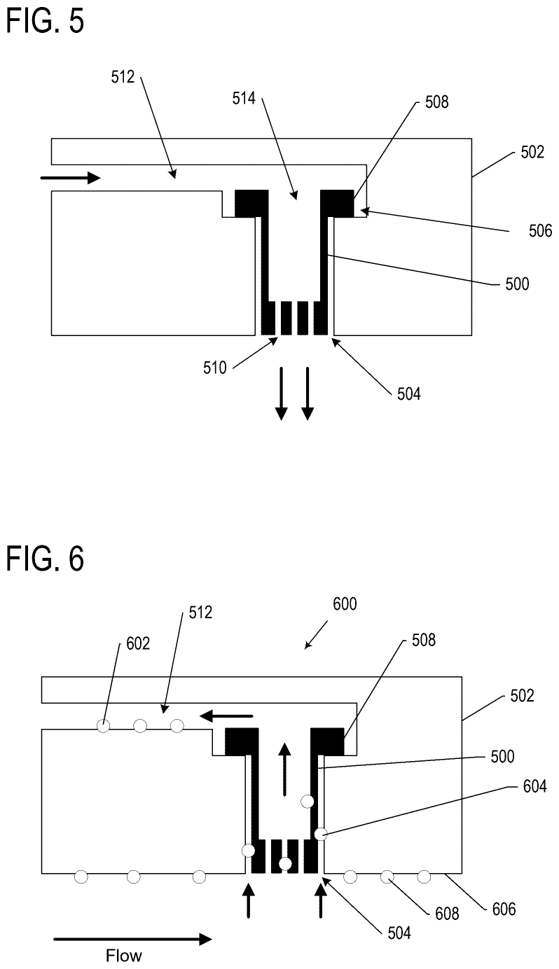

FIG. 5 shows a schematic side view of an example insert 500 disposed within an outlet 504 of an example showerhead 502. The outlet 504 of the showerhead 502 includes a cutout section 506 that accommodates a flange 508 of the insert 500. In some implementations, the insert sits within the opening 504. In other implementations, the insert 500 is affixed to the showerhead 502. The insert 500 can be affixed to the showerhead using various types of fasteners.

The insert 500 includes a plurality of openings 510. The plurality of openings 510 enables finer control of flow rates compared to using outlets 504 of the showerhead 502 without inserts 500. Processing gases introduced by the showerhead 502 can travel along a plenum 512, through a top opening 514 of the insert 500, and through the plurality of openings 510.

As described above, particles can form on surfaces of a ceramic showerhead during a cleaning process. For example, aluminum fluoride particles can form on an aluminum nitride showerhead. FIG. 6 schematically shows different locations on the showerhead-insert structure 600 at which particles can form during a cleaning process. One example location of particle formation is in the showerhead plenum 512. Particles formed in the showerhead plenum 512 are referred to herein as plenum particles 602. Another example location of particle formation is in a space between a wall of the outlet 504 and the insert 500. Particles on the surfaces of the insert 500 and the outlet 504 are referred to herein as insert hole particles 604. A further example location for particle formation is on a face 606 of the showerhead 502. Particles formed on outside surfaces of the showerhead are referred to herein as face particles 608.

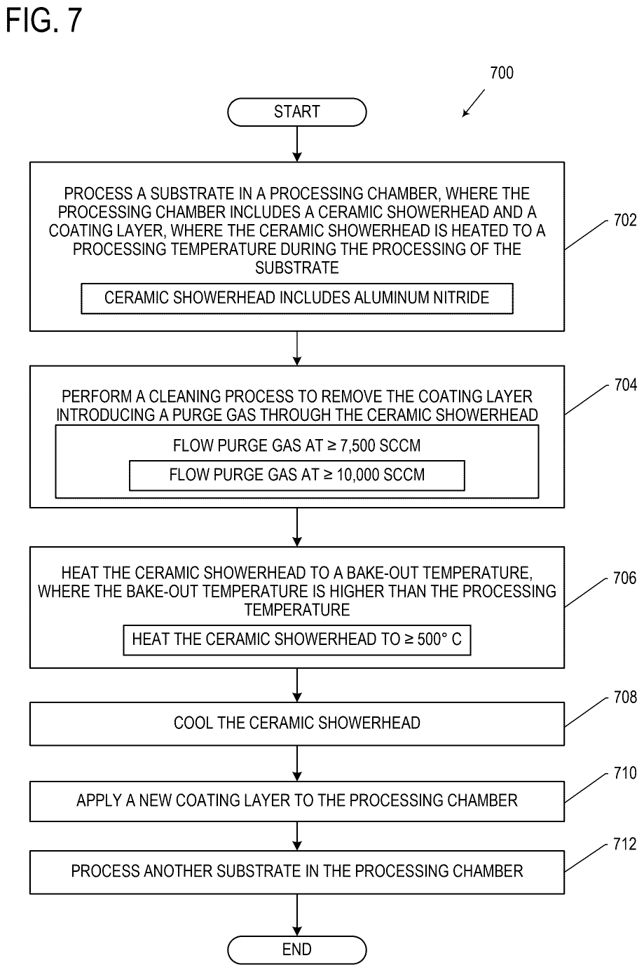

The particles depicted in FIG. 6 can contaminate a substrate. Such contamination can cause defects that spatially correspond to the outlets of the showerhead. Thus, FIG. 7 shows a flow diagram of an example method 700 for mitigating particle formation during a cleaning process.

At 702, the method 700 includes processing a substrate in the processing chamber. The processing chamber includes a ceramic showerhead and a coating. The ceramic showerhead is heated to a processing temperature during the processing of the substrate. The ceramic showerhead can comprise various materials. Examples include an aluminum nitride showerhead. The processing chamber can further include an insert disposed within an outlet of the ceramic showerhead. The coating can include an undercoat, a precoat, and/or material deposited during processing of the substrates.

At 704, the method 700 includes performing a cleaning process to remove the coating. The cleaning process can be performed by introducing a reactive cleaning species into the processing chamber while flowing a purge gas through the ceramic showerhead. In some implementations, the reactive cleaning species is generated in a remote plasma chamber. Further, in some implementations, the reactive cleaning species is generated alternatively or additionally in an in-situ plasma within the processing chamber. Different reactive cleaning species can be used. For example, where a silicon-containing coating is being cleaned, the reactive cleaning species can include fluorine radicals generated from a cleaning species precursor such as nitrogen trifluoride gas. In other examples, fluorine radicals can be generated from other cleaning species precursors. In some implementations, the purge gas flows through the ceramic showerhead at a flow rate of at least 7,500 sccm. In further implementations, the purge gas flows through the ceramic showerhead at a flow rate of at least 10,000 sccm. Such flow rates may help to reduce or prevent backflow of the reactive cleaning species into the showerhead plenum. This helps to reduce or avoid forming plenum particles during the cleaning process.

Continuing, at 706, the method 700 includes heating the ceramic showerhead to a bake-out temperature to remove at least some aluminum fluoride particles generated during the cleaning process. The bake-out temperature is a temperature that is above the processing temperature. Thermal expansion of the ceramic showerhead during the bake-out heating can dislodge aluminum fluoride particles adhering to the surfaces of the ceramic showerhead. For example, thermal expansion can dislodge at least some face particles and at least some insert hole particles. In some implementations, the bake-out temperature is at least 500 degrees Celsius. In further implementations, the bake-out temperature is at least 520 degrees Celsius. In yet further implementations, the bake-out temperature is at least 550 degrees Celsius. While heating the ceramic showerhead, a chamber evacuation system is operated to remove dislodged particles from the processing chamber.

At 708, the method 700 includes cooling the ceramic showerhead. In some examples, the ceramic showerhead may be cooled to the processing temperature. In other examples, the ceramic showerhead may be cooled to a temperature different than the processing temperature. The cooling can be performed actively or passively.

At 710, the method 700 includes applying a new coating to the processing chamber. The new coating can be applied at a processing temperature, or at a temperature different than a processing temperature. After applying the new coating, method 700 comprises processing another substrate in the processing chamber, at 712. Deposition processes may be performed on a new batch of substrates.

While method 700 comprises both a purge gas flow to prevent backflow of radicals into a showerhead plenum and also a bake-out process, in other examples, one these processes may be performed without the other.

Referring back to 704, relatively higher purge gas flow rates through the ceramic showerhead and insert during a cleaning process can lessen backflow through the ceramic showerhead more effectively than relatively lower flow rates. However, relatively higher flow rates can lead to the growth of crystals that extend from a showerhead toward a pedestal. The crystals may comprise coating materials and/or materials deposited on a substrate.

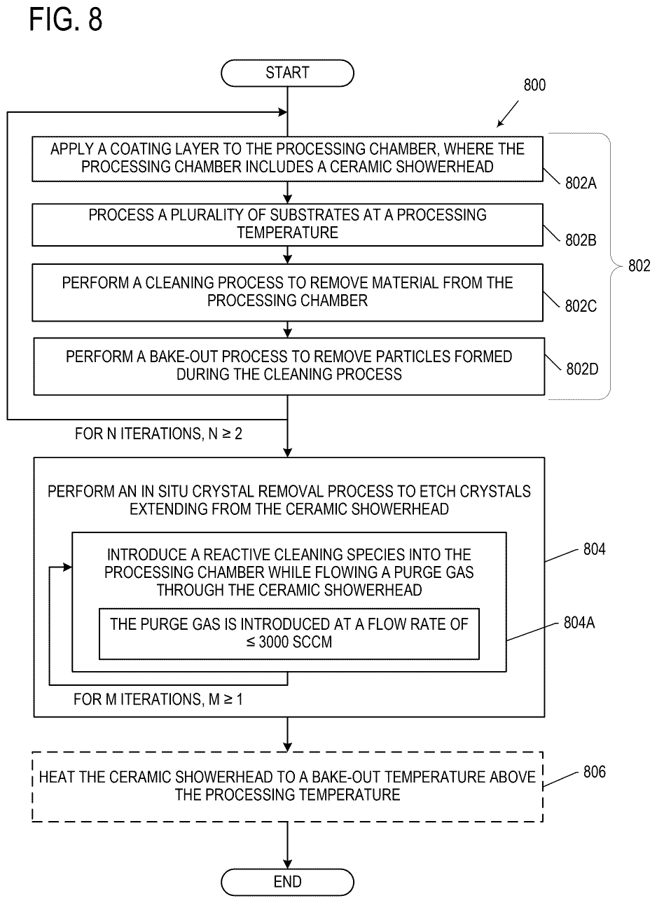

Various processes can be performed to remove these crystals. One process includes opening the chamber and performing a wet clean of the showerhead. For example, an isopropyl alcohol clean can be performed to remove the crystals. However, as described above, such a process can cause substantial tool downtime. As such, FIG. 8 shows a flow diagram of an example method 800 for operating a deposition tool that addresses crystal formation by an in-situ crystal etching process that may utilize less downtime.

At step 802, the method 800 includes performing a plurality of substrate batch processing cycles in a processing chamber. The processing chamber includes a ceramic showerhead. Each substrate batch processing cycle can include applying a coating to a processing chamber at substep 802A, processing a plurality of substrates at a processing temperature at substep 802B, performing a cleaning process at substep 802C, and performing a bake-out process at substep 802D. Substrate batch processing cycles can be performed for N iterations. In some implementations, more than 1,000 substrate batch processing cycles are performed. The substrates are processed at a processing temperature. The cleaning process can be performed using any of the cleaning processes described above. For example, the cleaning process can include introducing a reactive cleaning species into the processing chamber to remove the coating and/or deposited material from the processing chamber. The cleaning process can include introducing a purge gas through the ceramic showerhead at a predetermined flow rate. In some implementations, the ceramic showerhead introduces the purge gas at a flow rate of at least 7,500 sccm. In further implementations, the ceramic showerhead introduces the purge gas at a flow rate of at least 10,000 sccm. The bake-out process can be performed using any of the example bake-out processes described above.

At step 804, the method 800 includes performing an in situ crystal removal process to etch crystals extending from the ceramic showerhead. The in situ crystal removal process includes a plurality of crystal etch cycles. Each crystal etch cycle comprises, at substep 804A, introducing a reactive cleaning species into the processing chamber while flowing a purge gas through the ceramic showerhead. The purge gas can be introduced through the ceramic showerhead at a flow rate of less than or equal to 3,000 sccm. In some implementations, the purge gas is introduced through the ceramic showerhead at a flow rate of less or equal to than 1,000 sccm. The purge gas can be introduced through the ceramic showerhead at a same flow rate or at different flow rates for each crystal etch cycle. For example, the in situ crystal removal process can include performing a first crystal etch cycle and a second crystal etch cycle. The first crystal etch cycle can include introducing a purge gas through the ceramic showerhead at a flow rate of less than 2,000 sccm. The second crystal etch cycle can include introducing a purge gas through the ceramic showerhead at a flow rate of less than 3,000 sccm. In further implementations, the purge gases are introduced at flow rates of less than 1,000 sccm and 2,000 sccm for the first and second crystal etch cycles, respectively.

At step 806, the method 800 can optionally include heating the ceramic showerhead to a bake-out temperature. The ceramic showerhead can be heated to remove at least some aluminum fluoride particles generated during the in-situ crystal removal process. As described above, the bake-out temperature is above the processing temperature. In some implementations, the bake-out temperature is at least 500 degrees Celsius. In further implementations, the bake-out temperature is at least 520 degrees Celsius. In further implementations, the bake-out temperature is at least 550 degrees Celsius.

The disclosed examples provide for the cleaning of a deposition chamber while reducing risks posed by particle formation during cleaning. As such, the disclosed examples may allow a greater number of substrates to be processed between wet cleans. This may allow higher throughput than where a relatively greater number of wet cleans are required.

In some embodiments, the methods and processes described herein may be tied to a computing system of one or more computing devices. In particular, such methods and processes may be implemented as a computer-application program or service, an application-programming interface (API), a library, and/or other computer-program product.

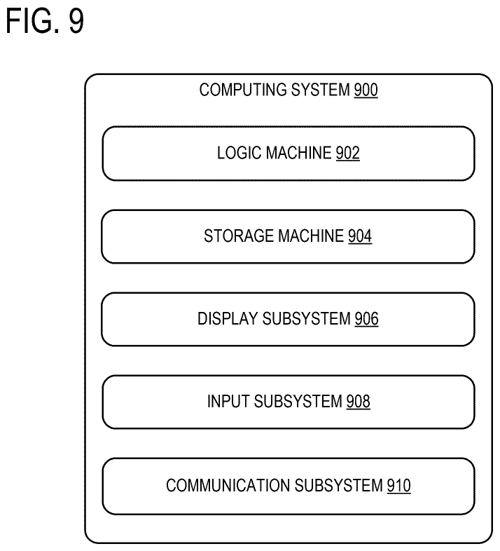

FIG. 9 schematically shows a non-limiting embodiment of a computing system 1200 that can enact one or more of the methods and processes described above. Computing system 900 is shown in simplified form. Computing system 900 may take the form of one or more personal computers, server computers, tablet computers, home-entertainment computers, network computing devices, mobile computing devices, mobile communication devices (e.g., smart phone), and/or other computing devices. The computing system 900 can enact one or more of the methods and processes described above. For example, the computing system 900 can be implemented as the controller for the deposition tools described in FIGS. 1 and 2.

Computing system 900 includes a logic machine 902 and a storage machine 904. Computing system 900 may optionally include a display subsystem 906, input subsystem 908, communication subsystem 910, and/or other components not shown in FIG. 9.

Logic machine 902 includes one or more physical devices configured to execute instructions. For example, the logic machine 902 may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine 902 may include one or more processors configured to execute software instructions. Additionally or alternatively, the logic machine 902 may include one or more hardware or firmware logic machines configured to execute hardware or firmware instructions. Processors of the logic machine 902 may be single-core or multi-core, and the instructions executed thereon may be configured for sequential, parallel, and/or distributed processing. Individual components of the logic machine 902 optionally may be distributed among two or more separate devices, which may be remotely located and/or configured for coordinated processing. Aspects of the logic machine 902 may be virtualized and executed by remotely accessible, networked computing devices configured in a cloud-computing configuration.

Storage machine 904 includes one or more physical devices configured to hold instructions executable by the logic machine 902 to implement the methods and processes described herein. When such methods and processes are implemented, the state of storage machine 904 may be transformed-e.g., to hold different data.

Storage machine 904 may include removable and/or built-in devices. Storage machine 904 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 904 may include volatile, nonvolatile, dynamic, static, read/write, read-only, random-access, sequential-access, location-addressable, file-addressable, and/or content-addressable devices.

It will be appreciated that storage machine 904 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 902 and storage machine 904 may be integrated together into one or more hardware-logic components. Such hardware-logic components may include field-programmable gate arrays (FPGAs), program-and application-specific integrated circuits (PASIC/ASICs), program-and application-specific standard products (PSSP/ASSPs), system-on-a-chip (SOC), and complex programmable logic devices (CPLDs), for example.

The terms “module,” “program,” and “engine” may be used to describe an aspect of computing system 900 implemented to perform a particular function. In some cases, a module, program, or engine may be instantiated via logic machine 902 executing instructions held by storage machine 904. It will be understood that different modules, programs, and/or engines may be instantiated from the same application, service, code block, object, library, routine, API, function, etc. Likewise, the same module, program, and/or engine may be instantiated by different applications, services, code blocks, objects, routines, APIs, functions, etc. The terms “module,” “program,” and “engine” may encompass individual or groups of executable files, data files, libraries, drivers, scripts, database records, etc.

It will be appreciated that a “service”, as used herein, is an application program executable across multiple user sessions. A service may be available to one or more system components, programs, and/or other services. In some implementations, a service may run on one or more server-computing devices.

When included, display subsystem 906 may be used to present a visual representation of data held by storage machine 904. This visual representation may take the form of a graphical user interface (GUI). As the herein described methods and processes change the data held by the storage machine 904, and thus transform the state of the storage machine 904, the state of display subsystem 906 may likewise be transformed to visually represent changes in the underlying data. Display subsystem 906 may include one or more display devices utilizing virtually any type of technology. Such display devices may be combined with logic machine 902 and/or storage machine 904 in a shared enclosure, or such display devices may be peripheral display devices.

When included, input subsystem 908 may comprise or interface with one or more user-input devices such as a keyboard, mouse, or touch screen. In some embodiments, the input subsystem 908 may comprise or interface with selected natural user input (NUI) componentry. Such componentry may be integrated or peripheral, and the transduction and/or processing of input actions may be handled on-or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition; as well as electric-field sensing componentry for assessing brain activity.

When included, communication subsystem 910 may be configured to communicatively couple computing system 900 with one or more other computing devices. Communication subsystem 910 may include wired and/or wireless communication devices compatible with one or more different communication protocols. As non-limiting examples, the communication subsystem 910 may be configured for communication via a wireless telephone network, or a wired or wireless local-or wide-area network. In some embodiments, the communication subsystem 910 may allow computing system 900 to send and/or receive messages to and/or from other devices via a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method for operating a deposition tool, the method comprising:
processing a substrate in a processing chamber comprising a ceramic showerhead and a coating, wherein the ceramic showerhead is heated to a processing temperature during the processing of the substrate;
performing a cleaning process to remove the coating by introducing a reactive cleaning species into the processing chamber while flowing a purge gas through the ceramic showerhead;
after performing the cleaning process, heating the ceramic showerhead to a bake-out temperature above the processing temperature to remove at least some particles generated during the cleaning process; and
applying a new coating to the processing chamber.

2. The method of claim 1, wherein applying the new coating comprises applying one or more of a silicon oxide or a silicon nitride coating to surfaces within the processing chamber.

3. The method of claim 1, further comprising cooling the ceramic showerhead to the processing temperature before applying the new coating.

4. The method of claim 1, wherein the bake-out temperature is at least 520 degrees Celsius.

5. The method of claim 1, wherein the purge gas flows through the ceramic showerhead at a flow rate of at least 7,500 standard cubic centimeters per minute.

6. The method of claim 5, wherein the purge gas flows through the ceramic showerhead at a flow rate of at least 10,000 standard cubic centimeters per minute.

7. The method of claim 1, wherein the ceramic showerhead comprises aluminum nitride and the particles comprise aluminum fluoride.

8. The method of claim 1, wherein the processing chamber further comprises an insert disposed within an outlet of the ceramic showerhead, and heating the ceramic showerhead to the bake-out temperature comprises dislodging at least some particles from between a wall of the outlet and a side of the insert.

9. A deposition tool, comprising:
a processing chamber;
a showerhead for introducing processing gases into the processing chamber, wherein the showerhead comprises a heater;
a plasma generator in fluid communication with the processing chamber; and
a controller comprising executable instructions to control the deposition tool to:
apply a first coating to the processing chamber;
heat the showerhead to a processing temperature;
process a substrate in the processing chamber;
flow a purge gas through the showerhead;
generate a reactive cleaning species using the plasma generator to remove the first coating;
heat the showerhead to a bake-out temperature above the processing temperature using the heater to remove at least some aluminum fluoride particles generated during the removal of the first coating; and
apply a second coating to the processing chamber.

10. The deposition tool of claim 9, wherein applying the second coating comprises applying one or more of a silicon oxide or a silicon nitride layer to surfaces within the processing chamber.

11. The deposition tool of claim 9, wherein the controller further comprises instructions executable to cool the showerhead to the processing temperature before applying the second coating.

12. The deposition tool of claim 9, wherein the instructions executable to heat the showerhead to the bake-out temperature are executable to heat the showerhead to a temperature of at least 520 degrees Celsius.

13. The deposition tool of claim 9, wherein the instructions executable to flow the purge gas through the showerhead are executable to flow the purge gas at a flow rate of at least 7,500 standard cubic centimeters per minute.

14. The deposition tool of claim 13, wherein the instructions executable to flow the purge gas through the showerhead are executable to flow the purge gas at a flow rate of at least 10,000 standard cubic centimeters per minute.

15. The deposition tool of claim 9, wherein the showerhead comprises aluminum nitride.

16. The deposition tool of claim 9, wherein the reactive cleaning species comprise fluorine radicals.

17. A method for operating a deposition tool, the method comprising:
performing a first plurality of substrate batch processing cycles in a processing chamber, wherein the processing chamber comprises a ceramic showerhead, wherein each substrate batch processing cycle comprises:
applying a coating to the processing chamber;
processing a batch of substrates; and
performing a cleaning process to remove the coating from the processing chamber; and
after performing the first plurality of substrate batch processing cycles, performing an in situ crystal removal process to etch crystals extending from the showerhead.

18. The method of claim 17, wherein performing the in situ crystal removal process comprises introducing a reactive cleaning species into the processing chamber while flowing a purge gas through the ceramic showerhead, wherein the purge gas is introduced through the ceramic showerhead at a flow rate of equal to or less than 3,000 standard cubic centimeters per minute.

19. The method of claim 17, wherein performing the in situ crystal removal process comprises performing a plurality of crystal etch process cycles, wherein each crystal etch process cycle comprises introducing a reactive cleaning species into the processing chamber while flowing a purge gas through the ceramic showerhead.

20. The method of claim 17, wherein the plurality of substrates is processed at a processing temperature, and wherein the method further comprises heating the ceramic showerhead to a bake-out temperature above the processing temperature to remove at least some aluminum fluoride particles generated during the cleaning process.
